(19) United States
(12) Patent Application Publication
(10) Pub. No.: US 2025/0365885 A1
(43) Pub. Date: Nov. 27, 2025

(54) FULL-AREA TOUCH PANEL DEVICE

(71) Applicant: SUNREX TECHNOLOGY CORP., Taichung City (TW)

(72) Inventors: Chun-Chieh CHEN, Taichung City (TW); Cheng-Yu CHUANG, Taichung City (TW); Yi-Wen TSAI, Taichung City (TW); Ching-Yao HUANG, Taichung City (TW); Ling-Cheng TSENG, Taichung City (TW)

(21) Appl. No.: 19/021,578

(22) Filed: Jan. 15, 2025

(30) Foreign Application Priority Data
May 22, 2024 (TW) 113205229

(51) Int. Cl. H05K 7/18

(52) U.S. Cl. CPC H05K 7/18

(57) ABSTRACT

A full-area touch panel device includes two first frame parts and two second frame parts each interconnecting the first frame parts. Two elastic members are disposed between the first frame parts and are connected to the second frame parts. A main body part is disposed on bottom surfaces of the elastic members. Two first extension parts extend from the main body part. Each of the first extension parts has a distal end portion disposed atop one of the second frame parts. Two second extension parts extend from the main body part. Each of the second extension parts has a distal end portion disposed atop another one of the second frame parts. A thickness of the main body part is greater than a thickness of each of the first extension parts and the second extension parts.

### CROSS-REFERENCE TO RELATED APPLICATION

This application claims priority to Taiwanese Utility Model Patent Application No. 113205229, filed on May 22, 2024, the entire disclosure of which is incorporated by reference herein.

### FIELD

The disclosure relates to a touch panel device, and more particularly to a full-area touch panel device.

### BACKGROUND

In a portable computing device, a touch pad device is one of main input devices. In order to provide a comfortable feedback of using such a touch pad device, there is room for improvement.

### SUMMARY

Therefore, an object of the disclosure is to provide a full-area touch panel device that is improved as compared to the prior art.

According to the disclosure, a full-area touch panel device includes a surrounding frame, two elastic members, and a fixing member.

The surrounding frame includes two first frame parts and two second frame parts. The first frame parts are spaced apart from each other in a first direction, and are elongated in a second direction perpendicular to the first direction. The second frame parts are spaced apart from each other in the second direction, and are elongated in the first direction. Each of the second frame parts has opposite ends in the first direction that are connected respectively to the first frame parts.

The elastic members are spaced apart from each other in the first direction and are disposed between the first frame parts. Each of the elastic members has opposite ends in the second direction that are connected respectively to the second frame parts.

The fixing member includes a main body part, two first extension parts, and two second extension parts. The main body part is disposed on bottom surfaces of the elastic members. The first extension parts are spaced apart from each other in the first direction, and extend from the main body part in the second direction. Each of the first extension parts has a distal end portion disposed atop one of the second frame parts.

A thickness of the main body part perpendicular to the first direction and the second direction is greater than a thickness of each of the first extension parts and the second extension parts perpendicular to the first direction and the second direction.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a perspective view illustrating a full-area touch panel device according to an embodiment of the disclosure assembled to a plate unit and a mount seat.

FIG. 2 is an exploded perspective view of the embodiment illustrating the full-area touch panel device, the plate unit, and a mount seat.

FIG. 3 is a bottom view of the embodiment illustrating a surrounding frame, two elastic members, and a fixing member of the full-area touch panel device.

FIG. 4 is an exploded perspective view of the embodiment illustrating the surrounding frame, the elastic members, and the fixing member of the full-area touch panel device.

FIG. 5 is a sectional view taken along line V-V of FIG. 1.

FIG. 6 is a sectional view taken along line VI-VI of FIG. 1.

FIG. 7 is a sectional view similar to FIG. 5, but illustrating the full-area touch panel device in response to pressing of a left side of a touch plate of the plate unit.

FIG. 8 is a sectional view similar to FIG. 6, but illustrating the full-area touch panel device in response to the pressing of the left side of the touch plate of the plate unit.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

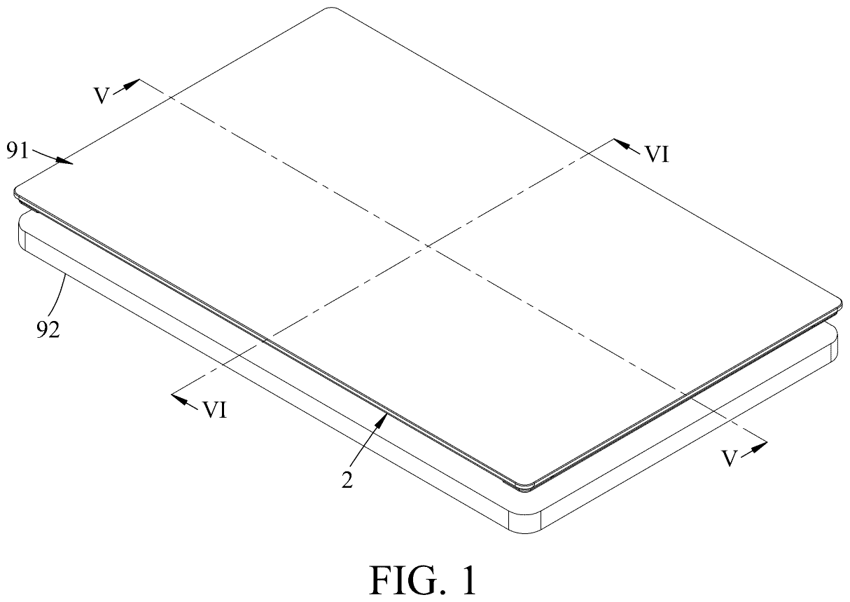

Referring to FIGS. 1 to 3, a full-area touch panel according to an embodiment of the disclosure is disposed between a plate unit 91 and a mount seat 92. The plate unit 91 includes a touch plate 911, a resilient plate 912 disposed in alignment with a center of the touch plate 911, and an auxiliary member 913 disposed under the resilient plate 912. In this embodiment, the resilient plate 912 is a metal dome. The auxiliary member 913 is made from a polyethylene terephthalate (PET) material or a sponge material. A thickness of the auxiliary member 913 is 0.195 mm.

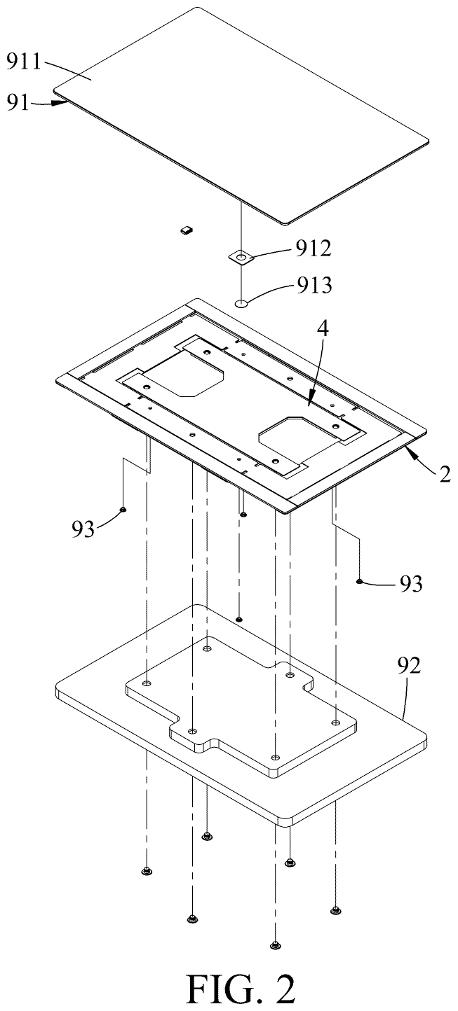

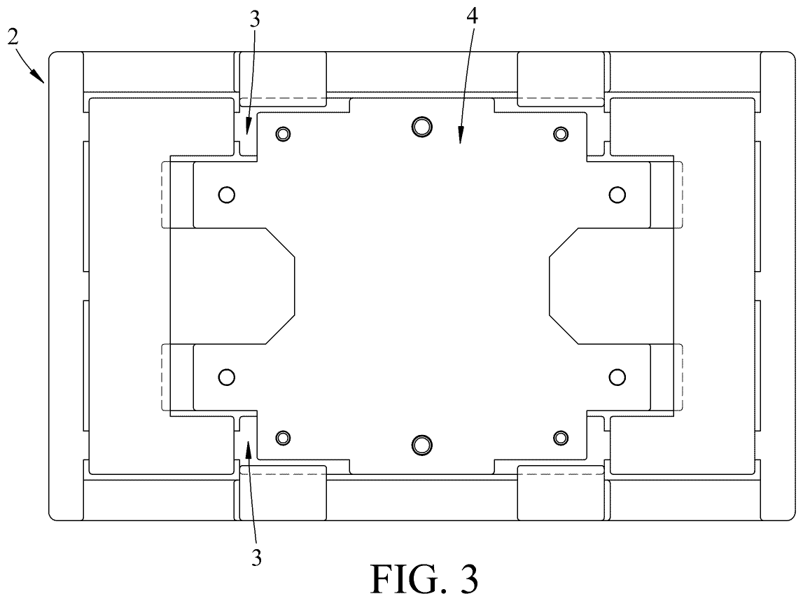

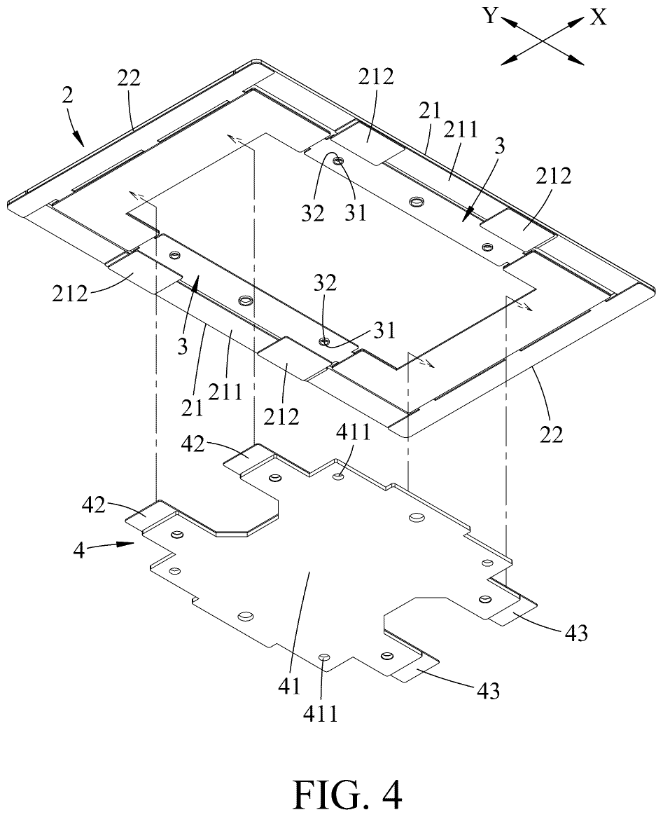

Referring to FIG. 4 in combination with FIGS. 2 and 3, the full-area touch panel device of the disclosure includes a surrounding frame 2, two elastic members 3, and a fixing member 4.

The surrounding frame 2 includes two first frame parts 21 and two second frame parts 22. The first frame parts 21 are spaced apart from each other in a first direction (X), and are elongated in a second direction (Y) perpendicular to the first direction (X). The second frame parts 22 are spaced apart from each other in the second direction (Y), and are elongated in the first direction (X). Each of the second frame parts 22 has opposite ends in the first direction (X) that are connected respectively to the first frame parts 21.

Each of the first frame parts 21 has an elongated portion 211 and two limiting portions 212. The elongated portion 211 extends in the second direction (Y). The limiting portions 212 are spaced apart from each other in the second direction (Y), and extend from the elongated portion 211 in the first direction (X). The limiting portions 212 of one of the first fixing parts 21 extend toward the elongated portion 211 of the other one of the first fixing parts 21.

The elastic members 3 are spaced apart from each other in the first direction (X) and are disposed between the first frame parts 21. Each of the elastic members 3 has opposite ends in the second direction (Y) that are connected respectively to the second frame parts 22. Each of the elastic members 3 has two threaded holes 31 and two positioning rings 32. The positioning rings 32 protrude downwardly from a bottom surface of the elastic member 3 and respectively surround the threaded holes 31. For each of the first frame parts 21, each of the limiting portions 212 has a distal end portion that is disposed under an adjacent one of the elastic members 3. Each of the elastic members 3 is flexible and may be forced to deform.

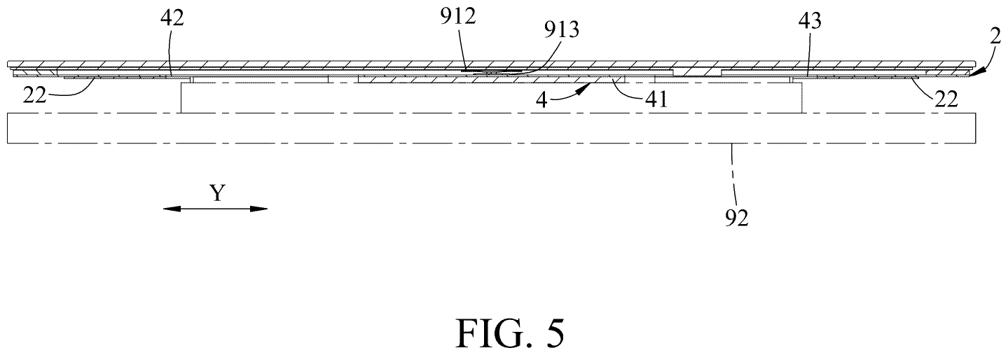

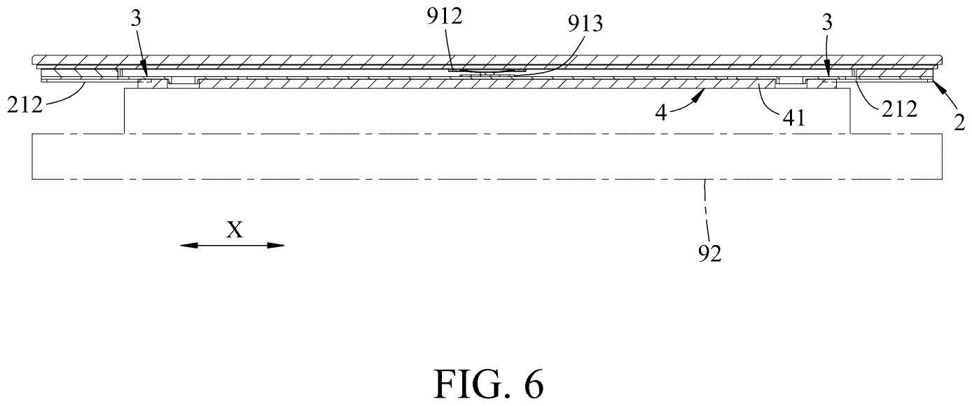

Referring to FIGS. 4, 5, and 6, the fixing member 4 includes a main body part 41, two first extension parts 42, and two second extension parts 43. The main body part 41 is disposed on bottom surfaces of the elastic members 3. The first extension parts 42 are spaced apart from each other in the first direction (X), and extend from the main body part 41 in the second direction (Y). Each of the first extension parts 42 has a distal end portion disposed atop one of the second frame parts 22. The second extension parts 43 are spaced apart from each other in the first direction (X), and extend from the main body part 41 opposite to the first extension parts 42 in the second direction (Y). Each of the second extension parts 43 has a distal end portion disposed atop another one of the second frame parts 22.

A thickness of the main body part 41 perpendicular to the first and second directions (X, Y) is greater than a thickness of each of the first extension parts 42 and the second extension parts 43 perpendicular to the first and second directions (X, Y). The main body part 41 of the fixing member 4 has four through holes 411 that are respectively aligned with the threaded holes 31 of the elastic members 3, and that are respectively engaged with the positioning rings 32 of the elastic members 3.

As shown in FIGS. 2, 4, and 5, during assembly of the full-area touch panel device of the disclosure, the touch plate 911 is disposed on the surrounding frame 2. The distal end portions of the first extension parts 42 of the fixing member 4 are disposed atop one of the second fixing parts 22, and the distal end portions of the second extension parts 43 of the fixing member 4 are disposed atop the other one of the second fixing parts 22, such that a bottom center of the pressing part 41 of the fixing member 4 abuts against the auxiliary member 913, and the auxiliary member 913 abuts against a bottom of the resilient plate 912. After the through holes 411 are respectively engaged with the positioning rings 32, and after four screws 93 extend through the through holes 411 and are screwed into the threaded holes 31, the elastic members 3 and the fixing member 4 are fixed. When the fixing member 4 is fixed to the mount seat 92, assembly of the full-area touch panel device of the disclosure is completed.

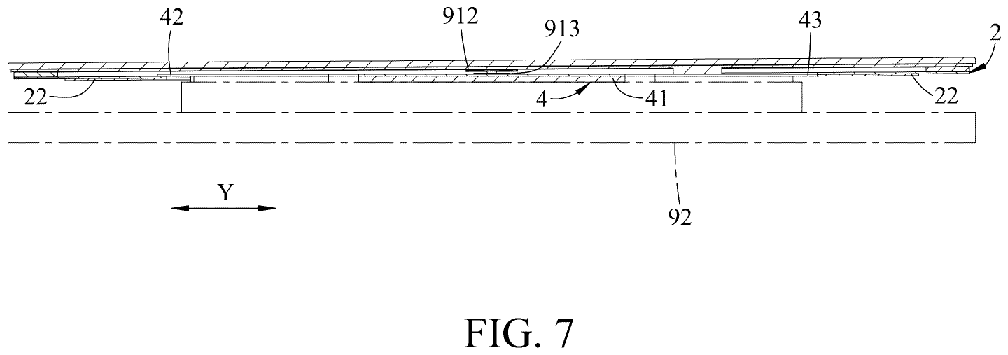

Referring to FIG. 7, two opposite sides of the touch plate 911 in the second direction (Y) (i.e., left and right sides of the touch plate 911 as shown in FIG. 7) will hereinafter be referred to as first and second sides of the touch plate 911. When the first side of the touch plate 911 is pressed, the auxiliary member 913 is driven by a reaction force of the fixing member 4 to press upwardly against the resilient plate 912, the left one of the second frame parts 22 is moved downwardly and detached from the first extension parts 42 (only one of the first extension parts 42 is shown in FIG. 7), and the right one of the second frame parts 22 is moved upwardly relative to the fixing member 4 that serves as a fulcrum and is restrained by the second extension parts 43 (only one of the second extension parts 43 is shown in FIG. 7). As a result, a feedback force is generated in response to pressing of the first side of the touch plate 911. Similarly, when the second side of the touch plate 911 is pressed, the upward movement of the left one of the second frame parts 22 is restrained by the first extension parts 42, such that a feedback force is generated in response to pressing of the second side of the mount seat 92.

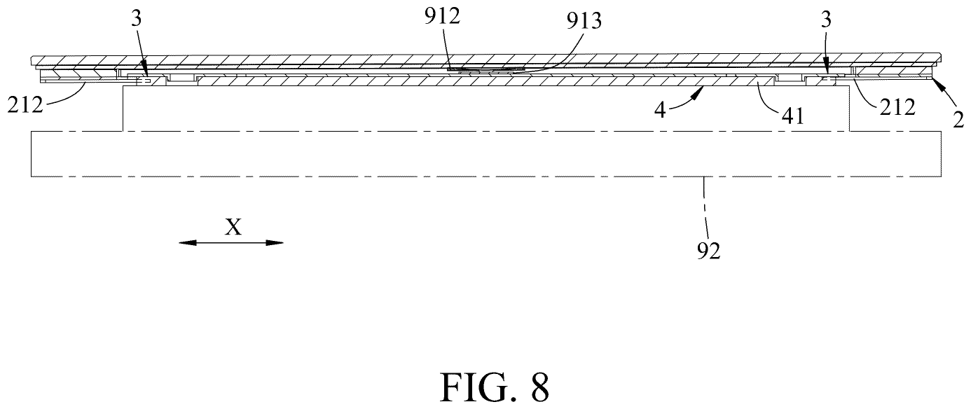

Referring to FIG. 8, two opposite sides of the touch plate 911 in the first direction (X) (i.e., left and right sides of the touch plate 911 in FIG. 8) will hereinafter be referred to as third and fourth sides of the touch plate 911. As shown in FIG. 8, when the third side of the touch plate 911 is pressed, the auxiliary member 913 is driven by the reaction force of the fixing member 4 to press upwardly against the resilient plate 912, the left one of the first frame parts 21 is moved downwardly, the left one of the elastic members 3 is driven by a reaction force of the main body part 41 and is bent upwardly, the limiting portions 212 (only one of the limiting portions 212 is shown in FIG. 8) of the left one of the first frames 21 are moved downwardly away from the main body part 41, the right one of the first frame 21 is moved upwardly relative to the fixing member 4 that serves as a fulcrum, and the upward movement of the limiting portions 212 (only one of the limiting portions 212 is shown in FIG. 8) of the right one of the first frames 21 is restrained by the right one of the elastic members 3. As a result, a feedback force is generated in response to pressing of the third side of the touch plate 911. Similarly, when the fourth side of the touch plate 911 is pressed, the upward movement of the limiting portions 212 (only one of the limiting portions 212 is shown in FIG. 8) of the left one of the first frames 21 is restrained by the left one of the elastic members 3, such that a feedback force is generated in response to pressing of the fourth side of the mount seat 92.

As shown in FIGS. 2, 3, 4, 7, and 8, when a corner of the touch plate 911 is pressed downwardly, one of the first extension parts 42 or one of the second extension parts 43 in position diagonally opposite to a pressed corner of the touch plate 911 restrains a corresponding one of the second frame parts 22, and the elastic members 3 in position diagonally opposite to the pressed corner of the touch plate 911 restrains a corresponding one of the limiting portions 212. As a result, a feedback force is generated in response to the pressed corner of the touch plate 911.

Specifically, because the thickness of the main body part 41 perpendicular to the first and second directions (X, Y) is greater than the thickness of each of the first extension parts 42 and the second extension parts 43 perpendicular to the first and second directions (X, Y), each of the first extension parts 42 and the second extension parts 43 is more elastic than the main body part 41. As a result, when the touch plate 911 is pressed, the full-area touch panel device of the disclosure may provide an elastic response to such pressing.

In summary, because the distal end portion of each of the first extension parts 42 is disposed atop one of the second frame parts 22, because the distal end portion of each of the second extension parts 43 is disposed atop another one of the second frame parts 22, and because the a distal end of each of the limiting portions 212 is disposed under the adjacent one of the elastic members 3, when any region of the touch plate 911 is pressed, a uniform feedback force may be generated in response to pressing of any region of the touch plate 911. Furthermore, because the thickness of the main body part 41 perpendicular to the first and second directions (X, Y) is greater than the thickness of each of the first extension parts 42 and the second extension parts 43 perpendicular to the first and second directions (X, Y), the full-area touch panel device of the disclosure may provide an elastic response to the pressing of any region of the touch plate 911, thereby improving the operation experience.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another 5 one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A full-area touch panel device comprising:
a surrounding frame including
two first frame parts that are spaced apart from each other in a first direction, and that are elongated in a second direction perpendicular to the first direction, and
two second frame parts that are spaced apart from each other in the second direction, and that are elongated in the first direction, each of said second frame parts having opposite ends in the first direction that are connected respectively to said first frame parts;
two elastic members that are spaced apart from each other in the first direction and that are disposed between said first frame parts, each of said elastic members having opposite ends in the second direction that are connected respectively to said second frame parts; and
a fixing member including
a main body part that is disposed on bottom surfaces of said elastic members,
two first extension parts that are spaced apart from each other in the first direction, and that extend from said main body part in the second direction, each of said first extension parts having a distal end portion disposed atop one of said second frame parts, and
two second extension parts that are spaced apart from each other in the first direction, and that extend from said main body part opposite to said first extension parts in the second direction, each of said second extension parts having a distal end portion disposed atop another one of said second frame parts;
wherein a thickness of said main body part perpendicular to the first direction and the second direction is greater than a thickness of each of said first extension parts and said second extension parts perpendicular to the first direction and the second direction.

2. The full-area touch panel device as claimed in claim 1, wherein each of said first frame parts has
an elongated portion that extends in the second direction, and
two limiting portions that are spaced apart from each other in the second direction, and that extend from said elongated portion in the first direction, each of said limiting portions having a distal end portion that is disposed under an adjacent one of said elastic members.

3. The full-area touch panel device as claimed in claim 1, wherein:
each of said elastic members has a plurality of threaded holes; and
said main body part of said fixing member has a plurality of through holes that are respectively aligned with said threaded holes of said elastic members.
